(19) United States
(12) Patent Application Publication
(10) Pub. No.: US 2011/0287344 A1
(43) Pub. Date: Nov. 24, 2011

(54) REFLECTIVE PHOTOMASK, MANUFACTURING METHOD OF THE PHOTOMASK, AND PATTERN FORMATION METHOD

(76) Inventor: Shigeo IRIE, Leuven (BE)

(21) Appl. No.: 13/029,637

(22) Filed: Feb. 17, 2011

(30) Foreign Application Priority Data
May 24, 2010 (JP) 2010-118164

(51) Int. Cl. G03F 1/00; G03F 7/20

(52) U.S. Cl. 430/5; 430/325

(57) ABSTRACT

A reflective photomask includes a phase shift portion, a reflective portion located outside the phase shift portion; and a semi-light-absorbing portion located between the phase shift portion and the reflective portion. The semi-light-absorbing portion includes a first multilayer film reflective to exposure light, a first interlayer film, a second multilayer film, a second interlayer film, and a third multilayer film. The phase shift portion is the first multilayer film exposed from the third multilayer film, the second interlayer film, the second multilayer film, the first interlayer film. The reflective portion is the second multilayer film exposed from the third multilayer film and the second interlayer film.

### CROSS-REFERENCE TO RELATED APPLICATION

This application claims priority to Japanese Patent Application No. 2010-118164 filed on May 24, 2010, the disclosure of which including the specification, the drawings, and the claims is hereby incorporated by reference in its entirety.

### BACKGROUND

The present disclosure relates to lithography techniques in manufacturing processes of semiconductor integrated circuit devices, and more particularly to reflective photomasks for extreme ultraviolet lithography, manufacturing methods of the photomasks, and pattern formation methods using the masks. In the specification, a reflective photomask for extreme ultraviolet lithography may be abbreviated to an “EUV mask,” where EUV stands for extreme ultraviolet.

With increasing miniaturization of semiconductor elements constituting semiconductor integrated circuits, reduction in pattern sizes of interconnects has been demanded. Lithography techniques using light with a short wavelength are needed to form fine patterns. In particular, in formation of a pattern with an interconnect width of 32 nm or less, a lithography technique using light (EUV light) with a wavelength of 13.6 nm is highly expected.

In lithography with krypton fluoride (KrF) excimer lasers (with a wavelength of 248 nm) or argon fluoride (ArF) excimer lasers (with a wavelength of 193 nm), a dioptric system including a lens made of synthetic quartz (a synthetic quartz lens) is used. However, EUV light has a shorter wavelength than output light from such excimer lasers. Thus, the synthetic quartz lens strongly absorbs EUV light, and a refractive index of the synthetic quartz lens is near 1 with the wavelength of the EUV light. Therefore, the above-described dioptric system cannot be used in EUV lithography, and a catoptric system (an optical system including a reflective photomask and a reflective mirror) is used. At present, in a mainstream reflective photomask, a multilayer film (a high-reflection region of EUV light) is formed on a low-thermal expansion glass substrate, and a pattern of an EUV light-absorbing film (a low-reflection region of the EUV light) is formed on the multilayer film. The multilayer film is formed by alternately stacking two types of thin films having different optical constants (refractive indexes or absorption indexes), and is, for example, a Mo/Si multilayer film of 40 layer pairs. In the specification, a “Mo/Si multilayer film of n layer pairs” denotes a film formed by alternately stacking Mo films and Si films n times.

It is generally known that the relationship between a wavelength of exposure light and resolution R is represented by the Rayleigh equation, R=k1×(λ/NA), where R is the minimum width of a trace to be resolved, NA is a numerical aperture of lenses in projection optics, and λ is a wavelength of EUV light (exposure light). The reference character k1 represents a process factor mainly determined by performance of resist, and selection of a super-resolution technique. It is known that k1 can be reduced to about 0.35 with use of suitable resist and a super-resolution technique. For example, where the reflective photomask is irradiated with EUV light with a wavelength of 13.6 nm in an exposure device with NA of 0.25, which is the maximum at present, and where k1 is 0.5 (k1=0.5 is the limit of k1 without using any super-resolution technique), it is found from the above-described Rayleigh equation that a pattern with a line width of 27 nm can be formed. That is, reduction in pattern widths, pattern pitches, etc. can be achieved by using EUV light and a reflective photomask capable of pattern transfer with the EUV light, which cannot be achieved by using output light from an ArF excimer laser, a light-transmissive mask, the dioptric system, etc.

However, in recent years, miniaturization of semiconductor elements has been increasingly demanded, and further reduction of pattern widths, pattern pitches, etc. are expected. For example, in a 16 nm generation logic pattern, a resist line width of 22 nm or less is becoming demanded, i.e., the condition where k1<0.5 is becoming demanded. In order to obtain a resist line width of 22 nm or less in an exposure device where the wavelength of EUV light is 13.6 nm and NA=0.25, k1=0.4 is obtained by the Rayleigh equation. In order to form such a line width, it is not sufficient to use EUV light with a wavelength of 13.6 nm and a reflective photomask reflecting the EUV light, and it is necessary to use a super-resolution technique improving resolution capabilities.

### SUMMARY

As a representative super-resolution techniques, a phase shift mask technique or an off-axis light source (annular illumination and quadrupole illumination, etc.) selectively utilizing ±first-order diffracted light of a mask pattern is known. The phase shift mask technique utilizes a phase difference of light, and is highly effective in improving resolution capabilities, and increasing pattern contrast. For example, a half-tone phase shift mask, a mask enhancer, etc. are known as the phase shift mask technique. A technique using a mask enhancer improves optical contrast and a depth of field (DOF) in pattern formation of any form, and is thus believed to be more excellent than the technique using a half-tone phase shift mask.

A phase shift portion can be easily formed in a transmissive photomask, but is extremely difficult to form in a reflective photomask.

For example, in a transmissive photomask, regions having different phases of transmitted light by 180° can be formed by trenching a mask substrate. However, if the technique is applied to a reflective photomask, not only the phases of reflected light but also reflectivity of exposure light changes. Therefore, a phase shift portion cannot be formed on a reflective photomask using this technique.

Also, in a transmissive photomask, regions having different phases of transmitted light by 180° can be formed by utilizing a phase shift effect of a material. No material is difficult to absorb EUV light. It is difficult to obtain desired reflectivity and phase shift effect of exposure light using a single material. Therefore, a phase shift portion cannot be formed in a reflective photomask even with this technique.

A structure of a mask enhancer, the principal of an improvement in contrast, and problems in manufacturing a mask, where a technique with a mask enhancer is applied to a reflective photomask, will be described below with reference to FIGS. 5A and 5B. FIG. 5A is a top view of a conventional reflective photomask having a structure with a mask enhancer. FIG. 5B is a cross-sectional view taken along the line VB-VB of FIG. 5A. The structure with a mask enhancer for improving resolution of gate line patterns located at regular intervals will be described. A positive resist process is used as an example. A line pattern is a portion of resist film not exposed by EUV light, i.e., a resist portion (a resist pattern) remaining after development. A space pattern is a portion of the resist film exposed by the EUV light, i.e., an opening portion formed by removing resist by the development (a resist removed pattern). Note that, where a negative resist process is used instead of the positive resist process, the definition of the line pattern may be replaced with a space pattern.

As shown in FIGS. 5A and 5B, a photomask includes a mask pattern 100 formed on a substrate 102 reflecting EUV light, a reflective portion 101 which is a portion not provided with the mask pattern 100 on the substrate 102. The mask pattern 100 is a gate pattern transferred by exposure, and includes a semi-light-absorbing portion 103, and a phase shifter 104. The semi-light-absorbing portion 103 has reflectivity to partially reflect EUV light. Reflected light at the semi-light-absorbing portion 103 and reflected light at the reflective portion 101 have similar phases. Reflected light at the phase shifter 104 and reflected light at the reflective portion 101 have opposite phases. As such, since the gate pattern includes the semi-light-absorbing portion 103 and the phase shifter 104, light reflected from the phase shifter 104 cancels part of the reflected light from the reflective portion 101 and the semi-light-absorbing portion 103. This enhances contrast of light intensity distribution in an optical image corresponding to the gate pattern.

Next, problems in manufacturing a reflective photomask having a structure with a mask enhancer will be described.

As shown in FIG. 5B, the substrate 102 is trenched by dry etching, and the trenched portion is the phase shifter 104. With this structure, reflected light from the phase shifter 104 can have an opposite phase to reflected light of the reflective portion 101 in the gate pattern (the mask pattern 100). However, since the phase shifter 104 is formed by dry etching, the phase shifter 104 has a rough surface. The wavelength of exposure light in exposure with EUV light is shorter than that in exposure with ArF excimer laser light, etc. by one-digit nm or more. Thus, the exposure with EUV is more severely influenced by unevenness of the surface of an EUV mask (the surface roughness on the phase shifter 104). This leads to scattering of light at the phase shifter 104, thereby causing reduction (a 10% or more reduction) in reflectivity of exposure light at the phase shifter 104.

When the amount of trenching the substrate 102 varies, the phase of reflected light at the phase shifter 104 also largely varies. Therefore, in some cases, the phase of the reflected light at the phase shifter 104 cannot be the inversion of the phase etc. of the reflected light at the reflective portion 101.

Moreover, in the structure with a mask enhancer, when reflected light at the semi-light-absorbing portion 103 and reflected light at the reflective portion 101 have similar phases, and exposure light at the semi-light-absorbing portion 103 has a reflectivity of 15% or less, the contrast of the light intensity distribution in an optical image corresponding to the gate pattern can be further enhanced. However, the reflective photomask shown in FIGS. 5A and 5B is difficult to obtain desired reflectivity and phase shift effect of exposure light using a single material. A feasible means needs to be used to obtain both of desired reflectivity and phase shift effect of exposure light.

Due to the three problems, it is difficult in a conventional reflective photomask, to precisely control reflectivity of exposure light in the regions (the reflective portion, the semi-light-absorbing portion, and the phase shifter) in the structure with a mask enhancer, and phase differences of reflected light among the regions. This reduces the contrast of the light intensity distribution in an optical image corresponding to a mask pattern (e.g., a gate pattern), resulting in the reduction in the dimensional accuracy of a transfer pattern on a wafer.

In view of the foregoing, it is an objective of the present disclosure to realize an EUV mask having a structure with a mask enhancer accurately controlling the reflectivity of exposure light and phase differences of reflected light, and a manufacturing method of the EUV mask, and to realize a fine transfer pattern formation method with a high dimensional accuracy using the EUV mask.

A manufacturing method of a reflective photomask according to the present disclosure includes the steps of: (a) sequentially forming a first multilayer film reflective to exposure light, a first interlayer film, a second multilayer film, a second interlayer film, and a third multilayer film on a glass substrate; (b) forming a phase shift portion by etching the third multilayer film, the second interlayer film, the second multilayer film, and the first interlayer film; (c) forming a reflective portion by etching portions of the third multilayer film and the second interlayer film which are located outside the phase shift portion; and (d) forming a semi-light-absorbing portion by retaining portions of the third multilayer film, the second interlayer film, the second multilayer film, the first interlayer film, and the first multilayer film which are located between the phase shift portion and the reflective portion without etching the portions.

In the manufacturing method of the reflective photomask of the present disclosure, since the first interlayer film and the second interlayer film are formed, the reflectivity of exposure light on the first multilayer film, the second multilayer film, and the third multilayer film has a desired value. Reflected light from the first multilayer film and reflected light from the second multilayer film have opposite phases, and reflected light from the third multilayer film and reflected light from the second multilayer film have similar phases.

In the manufacturing method of the reflective photomask of the present disclosure, where the first interlayer film has a thickness of m1, the second multilayer film has a thickness of d1, the second interlayer film has a thickness of m2, the third multilayer has a thickness of d2, an incident angle of the exposure light is φ, and the exposure light has a wavelength of λ, the following expressions are preferably satisfied.

0.95≦4(m1+d1)cos φ/(2n−1)λ≦1.05, where n is an integer, and

0.95≦4(m2+d2)cos φ/2nλ≦1.05, where n is an integer.

This feature enables a structure with a mask enhancer structure.

In the manufacturing method of the reflective photomask of the present disclosure, the first interlayer film preferably contains at least one of silicon dioxide, silicon nitride, ruthenium, and a compound containing ruthenium, and the second interlayer film preferably contains a compound containing tantalum. The compound containing ruthenium may be at least one of RuB, RuSi, RuNb, RuZr, RuMo, RuY, RuTi, and RuLa. The compound containing tantalum may be at least one of TaBN, TaB, TaBSi, TaBSiN, TaN, TaSi, TaSiN, TaGe, TaGeN, TaHf, TaHfN, TaZr, and TaZrN.

Ruthenium has a low absorption coefficient of exposure light, and thus, absorption of exposure light at the first interlayer film can be reduced. On the other hand, tantalum has a high absorption coefficient of exposure light, and thus, exposure light at the second interlayer film can be absorbed.

In the manufacturing method of the reflective photomask of the present disclosure, the step (b) preferably includes the steps of dry-etching the third multilayer film, the second interlayer film, and the second multilayer film, and wet-etching the first interlayer film. As such, the first interlayer film functions as an etching stop layer stopping the dry etching. Also, since the first interlayer film is removed by wet etching, roughness of the exposed surface of the first multilayer film due to dry etching can be reduced. This mitigates reduction in reflectivity of the exposure light on the exposed surface (phase shift portion) of the first multilayer film.

In the manufacturing method of the reflective photomask of the present disclosure, the step (c) includes the steps of dry-etching the third multilayer film, and wet-etching the second interlayer film. This mitigates reduction in reflectivity of the exposure light on the exposed surface (phase shift portion) of the second multilayer film.

A reflective photomask according to the present disclosure includes a phase shift portion; a reflective portion located outside the phase shift portion; and a semi-light-absorbing portion located between the phase shift portion and the reflective portion. The semi-light-absorbing portion includes a first multilayer film reflective to exposure light, a first interlayer film formed on the first multilayer film, a second multilayer film formed on the first interlayer film, a second interlayer film formed on the second multilayer film, and a third multilayer film formed on the second interlayer film. The phase shift portion is the first multilayer film exposed from the first interlayer film. The reflective portion is the second multilayer film exposed from the second interlayer film.

Since the reflective photomask according to the present disclosure includes the first interlayer film and the second interlayer film, the reflectivity of exposure light on the first multilayer film, the second multilayer film, and the third multilayer film has a desired value. Reflected light from the first multilayer film and reflected light from the second multilayer film have opposite phases, and reflected light from the third multilayer film and reflected light from the second multilayer film have similar phases.

In the reflective photomask of the present disclosure, the phase shift portion and the reflective portion preferably reflect the exposure light in opposite phases, and the semi-light-absorbing portion and the reflective portion preferably reflect the exposure light in similar phases. In the specification, the “opposite phases” mean that a phase difference ranges from (175 °+360°×n) to (185°+360°×n), where n is an integer. The “similar phases” mean that the phase difference ranges from (−5°+360°×n) to (5°+360°×n), where n is an integer. This enables the structure with a mask enhancer.

In the reflective photomask according to the present disclosure, where the first interlayer film has a thickness of m1, the second multilayer film has a thickness of d1, the second interlayer film has a thickness of m2, the third multilayer has a thickness of d2, an incident angle of the exposure light is φ, and the exposure light has a wavelength of λ; the following expressions are preferably satisfied.

0.95≦4(m1+d1)cos φ/(2n−1)λ≦1.05, where n is an integer, and

0.95≦4(m2+d2)cos φ/2nλ≦1.05, where n is an integer.

This enables a structure with a mask enhancer.

In the reflective photomask according to the present disclosure, the reflectivity of the exposure light at the semi-light-absorbing portion is preferably 15% or less.

In the reflective photomask according to the present disclosure, the first interlayer film preferably contains at least one of silicon dioxide, silicon nitride, ruthenium, and a compound containing ruthenium. The second interlayer film preferably contains a compound containing tantalum. The compound containing ruthenium is at least one of RuB, RuSi, RuNb, RuZr, RuMo, RuY, RuTi, and RuLa. The compound containing tantalum is at least one of TaBN, TaB, TaBSi, TaBSiN, TaN, TaSi, TaSiN, TaGe, TaGeN, TaHf, TaHfN, TaZr, and TaZrN. Ruthenium has a low absorption coefficient of exposure light, and thus, absorption of exposure light at the first interlayer film can be reduced. On the other hand, tantalum has a high absorption coefficient of exposure light, and thus, exposure light at the second interlayer film can be absorbed.

In a preferred embodiment described later, a phase shift portion is surrounded by a semi-light-absorbing portion. The semi-light-absorbing portion is surrounded by the reflective portion. With this structure, the reflective photomask according to the present disclosure can be utilized, for example, as a gate pattern.

In another preferred embodiment, the phase shift portion and the reflective portion are surrounded by the semi-light-absorbing portion. With this structure, the reflective photomask according to the present disclosure can be utilized, for example, as a contact hole pattern.

A transfer pattern formation method using the reflective photomask according to the present disclosure includes a formation step of a resist film on a substrate; an exposure step irradiating the resist film with light reflected by the reflective photomask according to the present disclosure; and a development step forming the pattern by developing the resist film after the exposure step. With this structure, a fine pattern with a high dimensional accuracy can be formed.

A pattern formation method according to the present disclosure preferably further includes a formation step of an underlying organic film on the substrate before the formation step of the resist film. This reduces an influence of secondary electrons generated from the substrate when irradiating with EUV light.

In a preferred embodiment described later, the exposure light has a wavelength of 13.6 nm.

As described above, according to the reflective photomask of the present disclosure, a manufacturing method of the photomask, and a pattern formation method, an EUV mask having a structure with a mask enhancer accurately controlling the reflectivity of exposure light and phase differences of reflected light, and a manufacturing method of the EUV mask can be realized, and a fine transfer pattern formation method with a high dimensional accuracy can be realized by using the EUV mask.

### BRIEF DESCRIPTION OF THE DRAWINGS

FIGS. 1A-1D are cross-sectional views illustrating a manufacturing method of a reflective photomask according to an example embodiment in order of steps.

FIGS. 2A-2D are cross-sectional views illustrating a manufacturing method of a reflective photomask according to another example embodiment in order of steps.

FIG. 3A is a top view of a reflective photomask according to an example embodiment. FIG. 3B is a cross-sectional view taken along the line IIIB-IIIB of FIG. 3A.

FIG. 4A is a top view of a reflective photomask according to another example embodiment. FIG. 4B is a cross-sectional view taken along the line IVB-IVB of FIG. 4A.

FIG. 4C is a top view of a reflective photomask according to another embodiment. FIG. 4D is a cross-sectional view taken along the line IVD-IVD of FIG. 4C.

FIG. 5A is a top view of a conventional reflective photomask. FIG. 5B is a cross-sectional view taken along the line VB-VB of FIG. 5A.

### DETAILED DESCRIPTION

### Assumption

Assumption for describing an example embodiment will be explained. Usually, a photomask is used in an exposure device of a reduced projection type, and thus, the reduction ratio of the exposure device needs to be considered when discussing a pattern size of the mask. However, in the description of the following embodiments, values of the sizes are calculated with the reduction ratio to avoid any confusion, if not otherwise specified, when a pattern size on a mask is explained in correspondence with a desired patter (e.g., resist pattern) to be formed. Specifically, where a resist pattern with a width of 32 nm is formed by a mask pattern with a width M×32 nm in a reduced projection system of one-M th, the mask pattern width and the resist pattern width are both 32 nm.

In the following example embodiments, NA represents a numerical aperture of lenses in the reduction projection optics in an exposure device, λ represents a wavelength of EUV light, and φ represents an oblique incident angle of the EUV light, if not otherwise specified.

### Example Embodiment

First, a manufacturing method of a reflective photomask according to an example embodiment will be described.

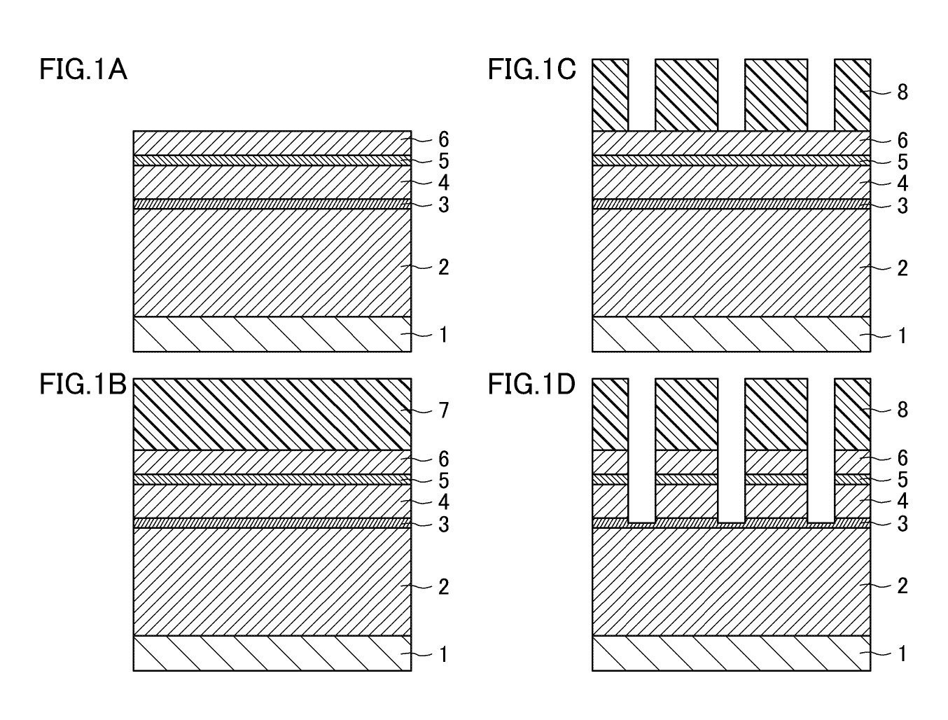

As shown in FIG. 1A, a first multilayer film 2, a first interlayer film 3, a second multilayer film 4, a second interlayer film 5, and a third multilayer film 6 are sequentially stacked on a low-thermal expansion glass substrate (glass substrate) 1 by magnetron sputtering (step (a)). The first multilayer film 2 is, for example, a Mo/Si multilayer film of 40 layer pairs, in which the thickness of a Mo film is, e.g., 2.8 nm, and the thickness of a Si film is, e.g., 4.0 nm. The first interlayer film 3 is, for example, a SiO₂ thin film with a thickness of 3.4 nm. The second multilayer film 4 is, for example, a Mo/Si multilayer film of 6 layer pairs. The second interlayer film 5 is, for example, a TaBN thin film with a thickness of 13.6 nm. The third multilayer film 6 is, for example, a Mo/Si multilayer film of 3 layer pairs.

Where the first interlayer film 3 has a thickness of m1, the second multilayer film 4 has a thickness of d1, the second interlayer film 5 has a thickness of m2, the third multilayer film 6 has a thickness of d2; thicknesses of the first interlayer film 3, the second multilayer film 4, the second interlayer film 5, and the third multilayer film 6 preferably satisfy the following two expressions (1) and (2). Note that a wavelength λ is 13.6 nm, and an incident angle φ is 6°.

0.95≦4(m1+d1)cos φ/(2n−1)λ≦1.05, where n is an integer Expression (1)

0.95≦4(m2+d2)cos φ/2nλ≦1.05, where n is an integer Expression (2)

As such, since the thicknesses of the first interlayer film 3, the second multilayer film 4, the second interlayer film 5, and the third multilayer film 6 satisfy the above expressions (1) and (2), reflected light from the first multilayer film 2 and reflected light from the second multilayer film 4 have opposite phases, and reflected light from the second multilayer film 4 and reflected light from the third multilayer film 6 have similar phases. This feature enables a structure with a mask enhancer.

The first multilayer film 2, the second multilayer film 4, and the third multilayer film 6 may be made of the following materials. Each of the first multilayer film 2, the second multilayer film 4, and the third multilayer film 6 is preferably a multilayer film formed by alternately stacking, as described above, high refractive index layers such as Mo films and low refractive index layers such as Si films a plurality of times. As the high refractive index layers, films containing a heavy element such as Cr, Ni, Mo, Ru, or W may be used other than the Mo films. As the low refractive index layers, films containing a light element such as Be, B, C, or Si may be used other than the Si films.

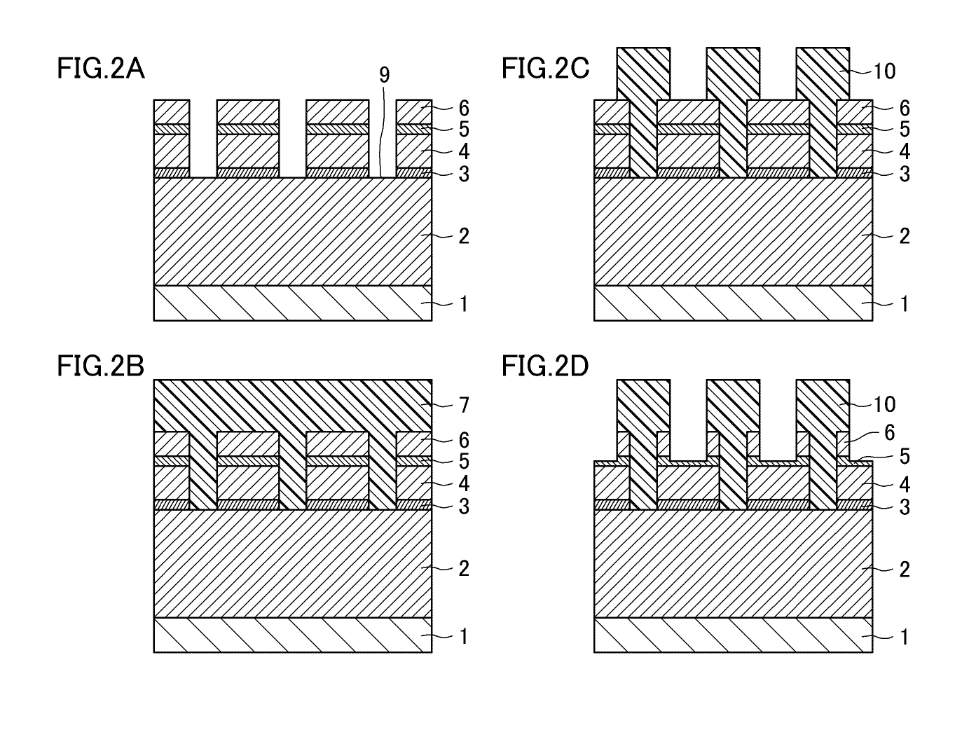

The first interlayer film 3 is preferably made of the following material. As will be described later in the step shown in FIG. 1D, the second multilayer film 4 and the third multilayer film 6 are selectively dry-etched to the vicinity of the surface of the first multilayer film 2 to form a phase shifter 9 (i.e., phase shift portion, see FIG. 2A) having the structure with a mask enhancer. The first interlayer film 3 is formed to reduce damages on the surface of the first multilayer film 2 by the dry etching, i.e., to protect the first multilayer film 2 from the dry etching.

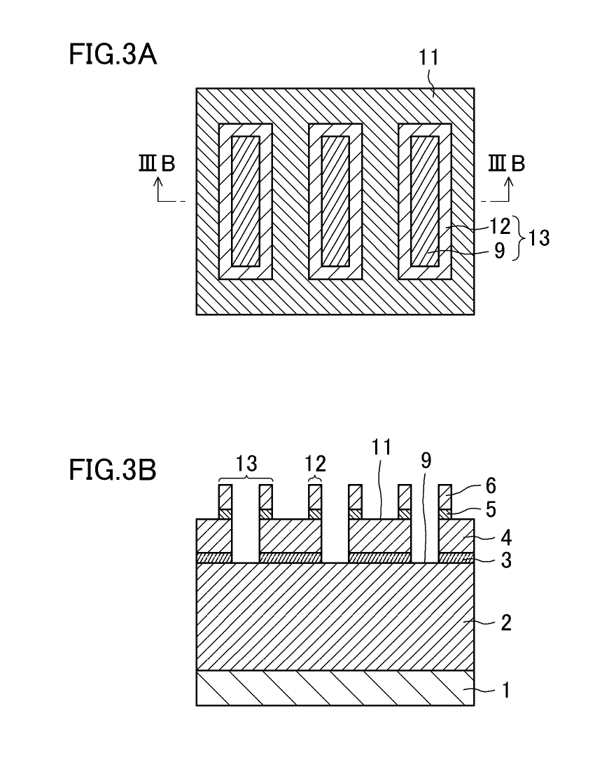

Note that the first interlayer film 3 is formed between the first multilayer film 2 and the second multilayer film 4. The second multilayer film 4 becomes, as shown in FIG. 3B etc., the reflective portion 11 reflective to exposure light (EUV light). The intensity of reflected light from the second multilayer film 4 is determined by the cumulative sum of reflected light from all of the first multilayer film 2, the first interlayer film 3, and the second multilayer film 4. As such, the intensity of reflected light from the second multilayer film 4 includes the intensity of reflected light from the first interlayer film 3. Thus, in order to increase the reflectivity of exposure light from the second multilayer film 4, the reflectivity of exposure light from the first interlayer film 3 is preferably increased. In other words, the first interlayer film 3 preferably has low absorption strength of EUV light. Therefore, the first interlayer film 3 is preferably made of a material transmissive to an EUV light wavelength, if possible.

From the foregoing, the first interlayer film 3 is preferably made of a material having a lower etching rate than a Mo/Si multilayer film (e.g., 1/10 or less), and less likely to be damaged by etching of the Mo/Si multilayer film. Furthermore, the first interlayer film 3 is preferably made of a material which can mitigate reduction in the reflectivity of exposure light as much as possible, and having an absorption coefficient of EUV light as low as possible. The absorption coefficient of EUV light is determined not by a molecule structure of a substance but by the type of the element. For example, the magnitude of the absorption coefficient of EUV light is represented by the inequality of Si<H<C<N<O<F<Al, and the material containing much Si has a low absorption coefficient of EUV light. Therefore, the first interlayer film 3 is preferably made of SiO₂, or may be Si₃N₄. Alternately, the first interlayer film 3 may be made of Ru or a compound containing Ru, since Ru has a low absorption coefficient of EUV light. That is, the first interlayer film 3 may be made of at least one of SiO₂, Si₃N₄, Ru, or a compound containing Ru. The compound containing Ru is at least one of RuB, RuSi, RuNb, RuZr, RuMo, RuY, RuTi, RuLa, etc.

The second interlayer film 5 is preferably made of the following material. As described later in the step shown in FIG. 2D, the third multilayer film 6 is selectively dry-etched to the vicinity of the surface of the second multilayer film 4 to form the reflective portion 11 having a structure with a mask enhancer (see FIG. 3B). The second interlayer film 5 is formed to reduce damages on the surface of the second multilayer film 4 by the dry etching, i.e., to protect the second multilayer film 4 from the dry etching.

Also, the second interlayer film 5 is provided to control the reflectivity and the phase of the reflected light from the third multilayer film 6. The intensity of the reflected light from the third multilayer film 6 includes the intensity of reflected light from the second interlayer film 5. Thus, in order to reduce the reflectivity of exposure light from the third multilayer film 6, the reflectivity of exposure light from the second interlayer film 5 is preferably reduced. In other words, the second interlayer film 5 preferably has high absorption strength of EUV light. Therefore, the second interlayer film 5 is preferably made of a material absorbing EUV light, if possible.

From the foregoing, the second interlayer film 5 is preferably made of a material having a lower etching rate than a Mo/Si multilayer film (e.g., 1/5 or less), and less likely to be damaged by etching of the Mo/Si multilayer film. Furthermore, the second interlayer film 5 is preferably made of a material having absorption coefficient as high as possible with respect to the wavelength of EUV light. The absorption coefficient of EUV light is not determined by a molecule structure of a substance but by the type of the element. Since Ta has a high absorption coefficient of EUV light, the material containing much Ti has a high absorption coefficient of EUV light. The compound containing Ta such as TaBN has a lower etching rate than a Mo/Si multilayer film, and is thus preferable as the material of the second interlayer film 5. The second interlayer film 5 may be made of a compound containing Ta other than TaBN. The Ta compound is at least one of TaB, TaBSi, TaBSiN, TaN, TaSi, TaSiN, TaGe, TaGeN, TaHf, TaHfN, TaZr, TaZrN, etc.

Next, as shown in FIG. 1B, resist 7 for electron beam is formed on the third multilayer film 6. Then, as shown in FIG. 1C, a first resist pattern 8 is formed from the resist 7 for electron beam on the third multilayer film 6 by electron beam drawing.

After that, as shown in FIG. 1D, the third multilayer film 6 is selectively etched with fluorine gas (e.g., SF₆ gas) by a reactive ion etching process using the first resist pattern 8 as an etching mask. Then, the second interlayer film 5 is selectively etched with chlorine gas (e.g., Cl₂ gas), and furthermore, the second multilayer film 4 is selectively etched with fluorine gas (e.g., SF₆ gas) again. The etching is stopped during the etching of the first interlayer film 3.

While in this step, dry etching is performed while switching the reactive gas among three stages of the SF₆ gas, Cl₂ gas, and SF₆ gas to form a pattern with high accuracy, dry etching may be performed with SF₆ gas without switching the reactive gas. The fluorine gas may be CF₄, C₂F₆, C₃F₆, C₄F₈, C₅F₈, CHF₃, CH₂F₂, or the like, other than SF₆ gas. With any fluorine gas, the three layers of the third multilayer film 6, the second interlayer film 5, and the second multilayer film 4 can be dry-etched at once. The chlorine gas may be BCl₃ gas other than Cl₂ gas.

Then, as shown in FIG. 2A, the first resist pattern 8 is removed by oxygen plasma ashing. After that, wet etching with hydrofluoric acid is performed to remove the first interlayer film 3 exposed from the third multilayer film 6, the second interlayer film 5, and the second multilayer film 4. As a result, the phase shifter 9 is formed (step (b)). In this step, wet etching solution may be mixed solution of hydrofluoric acid and ammonium fluoride, phosphoric acid, or the like other than hydrofluoric acid.

Next, as shown in FIG. 2B, the resist 7 for electron beam is formed on the third multilayer film 6 including the phase shifter 9. After that, as shown in FIG. 2C, a second resist pattern 10 is formed from the resist 7 for electron beam on the third multilayer film 6 including the phase shifter 9 by electron beam drawing.

Then, as shown in FIG. 2D, the third multilayer film 6 is selectively etched with fluorine gas (e.g., SF₆ gas) by a reactive ion etching process using the second resist pattern 10 as an etching mask. The etching is stopped while the second interlayer film 5 is selectively etched with chlorine gas (e.g., Cl₂ gas). While in this step as well, dry etching is performed while switching the gas between the two stages of the SF₆ gas and Cl₂ gas to form a pattern with high accuracy, dry etching may be performed with SF₆ gas without switching the reactive gas. The fluorine gas may be CF₄, C₂F₆, C₃F₆, C₄F₈, C₅F₈, CHF₃, CH₂F₂, or the like other than SF₆ gas. With any fluorine gas, the two layers of the third multilayer film 6, and the second interlayer film 5 can be dry-etched at once. The chlorine gas may be BCl₃ gas other than Cl₂ gas.

After that, the second resist pattern 10 is removed by oxygen plasma ashing. Then, wet etching with hydrofluoric acid is performed to remove the second interlayer film 5 exposed from the third multilayer film 6. As a result, as shown in FIGS. 3A and 3B, the reflective portion 11 and a semi-light-absorbing portion 12 are formed (steps (c) and (d)). In this step as well, wet etching solution may be mixed solution of hydrofluoric acid and ammonium fluoride, phosphoric acid, or the like, other than hydrofluoric acid.

The structure with a mask enhancer obtained by the above-described manufacturing method of the reflective photomask will be described below with reference to FIGS. 3A and 3B. The structure with a mask enhancer for improving resolution of gate line patterns located at regular intervals will be described here. A positive resist process is used as an example. A line pattern is a portion of a resist film not exposed by EUV light, i.e., a resist portion (a resist pattern) remaining after development. A space pattern is a portion of the resist film exposed by the EUV light, i.e., an opening portion formed by removing resist by the development (resist removed pattern). Note that, where a negative resist process is used instead of the positive resist process, the definition of the line pattern may be replaced with a space pattern.

As shown in FIG. 3A, the reflective photomask according to this example embodiment includes a mask pattern 13 formed on a low-thermal expansion glass substrate 1, and a reflective portion 11 not provided with the mask pattern 13. The mask pattern 13 is surrounded by the reflective portion 11, and a gate pattern transferred by exposure. This mask pattern 13 includes a semi-light-absorbing portion 12, and a phase shifter 9 surrounded by the semi-light-absorbing portion 12. The reflective portion 11 is reflective to exposure light, while the semi-light-absorbing portion 12 has first reflectivity (e.g., 15% or less) partially reflecting EUV light.

In the reflective photomask according to this example embodiment, reflected light at the phase shifter 9 and reflected light at the reflective portion 11 have opposite phases, while reflected light at the semi-light-absorbing portion 12 and reflected light to the reflective portion 11 have similar phases. As such, light reflected from the phase shifter 9 cancels part of the reflected light from the reflective portion 11 and the semi-light-absorbing portion 12. This enhances contrast of light intensity distribution in an optical image corresponding to the gate pattern.

Next, elements of the photomask according to this example embodiment will be described.

As shown in FIG. 3B, the phase shifter 9 is formed by the first multilayer film 2 formed on the low-thermal expansion glass substrate 1, and is the first multilayer film 2 exposed from the third multilayer film 6, the second interlayer film 5, the second multilayer film 4, and the first interlayer film 3. The semi-light-absorbing portion 12 is formed by the first multilayer film 2, the first interlayer film 3, the second multilayer film 4, the second interlayer film 5, and the third multilayer film 6, which are formed on the low-thermal expansion glass substrate 1; and is the third multilayer film 6 remaining without being etched. The reflective portion 11 is formed by the first multilayer film 2, the first interlayer film 3, and the second multilayer film 4, which are formed on the low-thermal expansion glass substrate 1; and is the second multilayer film 4 exposed from the third multilayer film 6 and the second interlayer film 5. Note that the structures of the first multilayer film 2, the first interlayer film 3, the second multilayer film 4, the second interlayer film 5, and the third multilayer film 6 are as described above.

When the reflective photomask according to this example embodiment is irradiated with EUV light with a wavelength of 13.6 nm at an incident angle of φ6°; reflected light at the first multilayer film 2 and reflected light at the second multilayer film 4 have opposite phases by 180°±5°, and reflected light at the second multilayer film 4 and reflected light at the third multilayer film 6 have similar phases by 0°±5°. As a result, it can be found that, in the reflective photomask according to this example embodiment, desired phase differences among reflected light at the phase shifter 9, the reflective portion 11, and the semi-light-absorbing portion 12 can be realized with high accuracy. Note that, where the first interlayer film 3 has a thickness of m1, the second multilayer film 4 has a thickness of d1, the second interlayer film 5 has a thickness of m2, and the third multilayer film 6 has a thickness of d2; the thicknesses of the first interlayer film 3, the second multilayer film 4, the second interlayer film 5, and the third multilayer film 6 preferably satisfy the above-described expressions (1) and (2).

The reflectivity of exposure light at the first multilayer film 2, the second multilayer film 4, and the third multilayer film 6 is 65%, 65%, and 5%, respectively. As such, with use of the photomask according to this example embodiment, desired reflectivity of exposure light can be achieved with high accuracy. One of the reasons why desired reflectivity of exposure light can be achieved with high accuracy is, for example, that the phase shifter 9 and the reflective portion 11 can be formed without causing surface roughness on the phase shifter 9 and the reflective portion 11.

Next, a result of mounting the reflective photomask shown in FIGS. 3A and 3B in an EUV exposure device and performing pattern transfer will be described. A gate pattern with a pitch of 56 nm and a size of 22 nm for a system large scale integration (LSI) of 22 nm generation is formed in the reflective photomask. The gate pattern includes the phase shifter 9 and the semi-light-absorbing portion 12. The phase shifter 9 has a width of 12 nm. The semi-light-absorbing portion 12 is formed to surround the phase shifter 9, and has a width of 5 nm. The reflective portion 11 is formed to surround the gate pattern. The reflective portion 11 between gate patterns has a width of 34 nm. For comparison, pattern transfer is performed using a photomask (a first reference mask) not provided with the first interlayer film 3 and the second interlayer film 5 in the reflective photomask provided with the gate pattern. The pattern transfer method will be described below.

First, an underlying organic film with a thickness of 20 nm is formed on a substrate (a silicon wafer) and baked at 205° C. for 60 seconds. Then, positive resist for EUV with a thickness of 50 nm is formed on the underlying organic film and pre-baked at 110° C. for 60 seconds. The substrate may be provided with various untreated films such as a silicon dioxide film or a silicon nitride film. The underlying organic film is provided not to reduce reflection from the substrate as in a conventional ArF lithography, but to reduce influences of secondary electrons generated from the substrate when irradiating with EUV light.

Next, a reflective photomask having a structure with a mask enhancer is mounted in an EUV exposure device to perform pattern transfer on the above-described wafer substrate (an exposure step). The NA of the EUV exposure device is 0.25, σ (=NA of a light source/NA of a projection lens) is 0.5, and the EUV light has a wavelength of 13.6 nm. Directly after the exposure, post exposure bake (PEB) is performed at 110° C. for 60 seconds to perform development with tetramethylammonium hydroxide (TMAH) solution with concentration of 2.38% (a development step). When the gate pattern formed in this manner is observed from above with an electron microscope to measure the gate pattern size, it is found that a gate pattern with a pitch of 56 nm and a size of 22 nm is formed. It is also found that a gate pattern with a pitch of 56 nm and a size of 22 nm is formed when a first reference mask is used. However, when the line edge roughness (LER) of a sidewall of the resist pattern is measured, it is 3.5 nm on the first reference mask, and is 2.7 nm on the photomask according to this example embodiment, which is improved by about 23% as compared to the first reference mask. The reason is considered as follows. With use of the first interlayer film 3 and the second interlayer film 5, the reflectivity of exposure light at the first multilayer film 2, the second multilayer film 4, and the third multilayer film 6 is accurately controlled, and phase differences in reflected light among the first multilayer film 2, the second multilayer film 4, and the third multilayer film 6 are accurately controlled, resulting in enhancement in contrast of light intensity distribution in an optical image corresponding to the gate pattern.

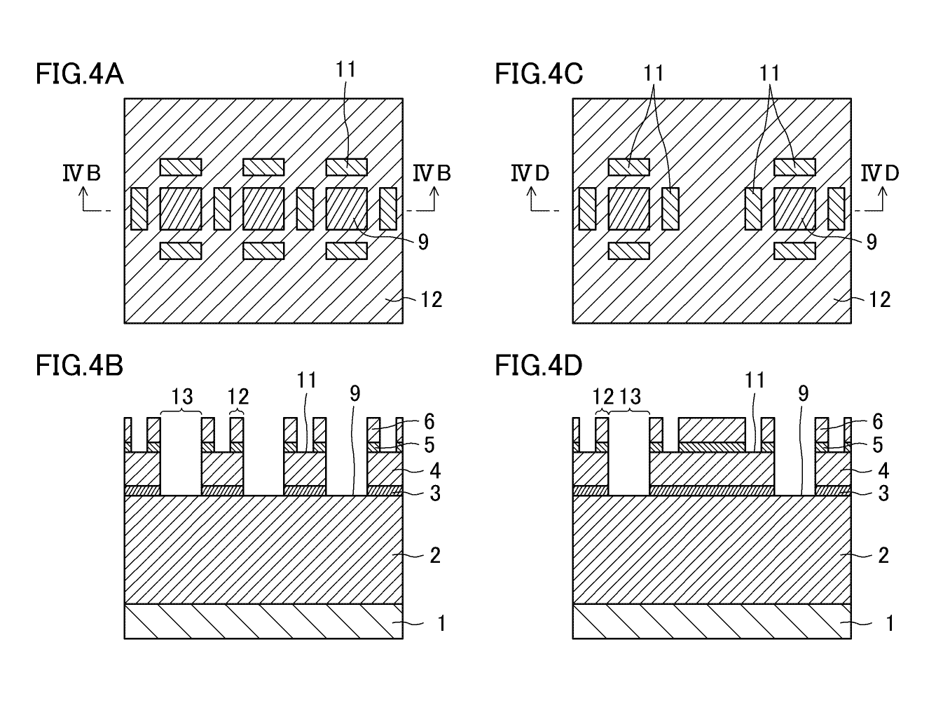

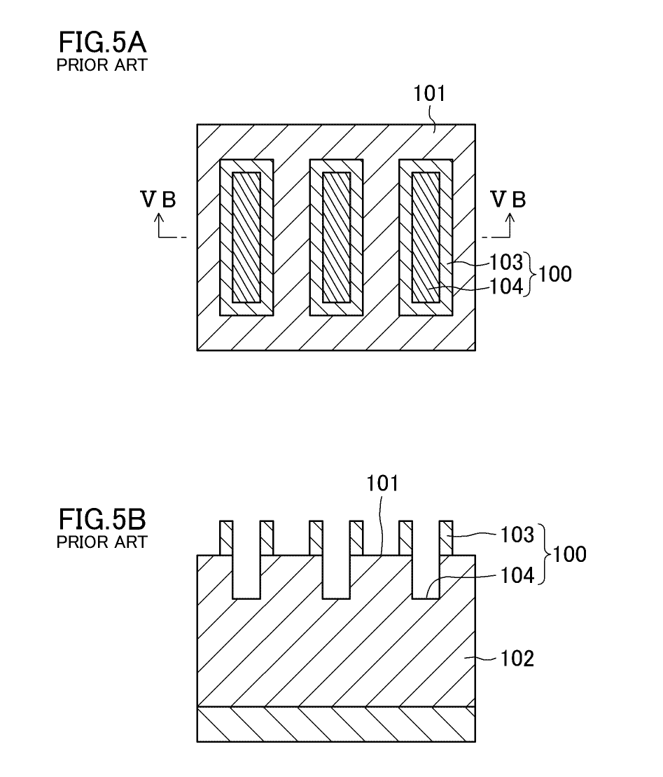

While the structure with a mask enhancer for forming a gate pattern has been described above, a structure with a mask enhancer for forming a fine contact hole pattern as shown in FIGS. 4A-4D provides similar advantages.

In the reflective photomask shown in FIGS. 4A and 4B, a contact hole pattern with a pitch of 56 nm and a size of 28 nm for a system LSI of 22 nm generation is formed. The contact hole pattern is composed of the phase shifter 9 only, and the phase shifter 9, which is in a square shape as viewed from above, is surrounded by the semi-light-absorbing portion 12. The reflective portion 11 of 18 nm×28 nm is formed in a region 28 nm apart from the center of the surface of the phase shifter 9 with the semi-light-absorbing portion 12 (with a width of 5 nm) interposed therebetween. The square reflective portions 11 as viewed from above are formed in vertically and horizontally symmetrical positions with the phase shifter 9 interposed therebetween in the figure. While a single reflective portion 11 is formed between adjacent phase shifters 9 in FIG. 4A, each of the phase shifters may have four reflective portions 11 at above, below, left and right positions, when the intervals of the phase shifter 9 are sufficiently large (FIGS. 4C and 4D).

A reflective photomask provided with such a contact hole pattern is mounted in an EUV exposure device to perform pattern transfer. For comparison, pattern transfer is performed at the same time using a photomask (a second reference mask) not provided with the first interlayer film 3 and the second interlayer film 5 in the reflective photomask provided with the gate pattern. The pattern transfer method will be described below.

First, an underlying organic film with a thickness of 20 nm is formed on a substrate (a silicon wafer) and baked at 205° C. for 60 seconds. Then, positive resist for EUV with a thickness of 50 nm is formed on the underlying organic film and pre-baked at 110° C. for 60 seconds. The substrate may be provided with various untreated films such as a silicon dioxide film or a silicon nitride film. The underlying organic film is provided not to reduce reflection from the substrate as in a conventional ArF lithography, but to reduce influences of secondary electrons generated from the substrate when irradiating with EUV light.

Next, a reflective photomask having a structure with a mask enhancer is mounted in an EUV exposure device to perform pattern transfer on the above-described wafer substrate. The NA of the EUV exposure device is 0.25, σ is 0.5, and the EUV light has a wavelength of 13.6 nm. Directly after the exposure, PEB is performed at 110° C. for 60 seconds to perform development with TMAH solution with concentration of 2.38%. The contact hole pattern formed in this manner is observed from above with an electron microscope to measure the size of the contact hole pattern. As a result, it is found that a contact hole pattern with a pitch of 56 nm and a size of 28 nm is formed. It is also found that a contact hole pattern with a pitch of 56 nm and a size of 28 nm is formed when a second reference mask is used. However, when the roughness (variations in the radius: 3σ) of the resist pattern is measured, it was 3.8 nm in the second reference mask, and was 3.3 nm in the photomask according to this example embodiment, which is improved by 15% as compared to the second reference mask. The reason is considered as follows. With use of the first interlayer film 3 and the second interlayer film 5, the reflectivity of exposure light at the first multilayer film 2, the second multilayer film 4, and the third multilayer film 6 is accurately controlled, and phase differences in reflected light among the first multilayer film 2, the second multilayer film 4, and the third multilayer film 6 are accurately controlled, resulting in enhancement in contrast of light intensity distribution in an optical image corresponding to the contact hole pattern.

As described above, the present disclosure relates to lithography in manufacturing processes of semiconductor integrated circuit devices, and more particularly to reflective photomasks for EUV light lithography, manufacturing methods of the photomasks, and pattern formation methods using the masks, and particularly useful for fine pattern formation.

What is claimed is:

1. A reflective photomask comprising:
a phase shift portion;
a reflective portion located outside the phase shift portion; and
a semi-light-absorbing portion located between the phase shift portion and the reflective portion; wherein
the semi-light-absorbing portion includes
a first multilayer film reflective to exposure light,
a first interlayer film formed on the first multilayer film,
a second multilayer film formed on the first interlayer film,
a second interlayer film formed on the second multilayer film, and
a third multilayer film formed on the second interlayer film,
the phase shift portion is the first multilayer film exposed from the third multilayer film, the second interlayer film, the second multilayer film, and the first interlayer film, and
the reflective portion is the second multilayer film exposed from the third multilayer film and the second interlayer film.

2. The reflective photomask of claim 1, wherein
the phase shift portion and the reflective portion reflect the exposure light in opposite phases, and
the semi-light-absorbing portion and the reflective portion reflect the exposure light in similar phases.

3. The reflective photomask of claim 2, wherein
the difference between the opposite phases ranges from (175°+360°×n) to (185°+360°×n), where n is an integer, and
the difference between the similar phases ranges from (−5°+360°×n) to (5°+360°×n), where n is an integer.

4. The reflective photomask of claim 1, wherein
0.95≦4(m1+d1) cos φ/(2n−1)λ≦1.05, where n is an integer, and
0.95≦4(m2+d2)cos φ/2nλ≦1.05, where n is an integer,
where the first interlayer film has a thickness of m1, the second multilayer film has a thickness of d1, the second interlayer film has a thickness of m2, the third multilayer has a thickness of d2, an incident angle of the exposure light is φ, and the exposure light has a wavelength of λ.

5. The reflective photomask of claim 1, wherein
the reflectivity of the exposure light at the semi-light-absorbing portion is 15% or less.

6. The reflective photomask of claim 1, wherein
the first interlayer film contains at least one of silicon dioxide, silicon nitride, ruthenium, and a compound containing ruthenium, and
the second interlayer film contains a compound containing tantalum.

7. The reflective photomask of claim 6, wherein
the compound containing ruthenium is at least one of RuB, RuSi, RuNb, RuZr, RuMo, RuY, RuTi, and RuLa.

8. The reflective photomask of claim 6, wherein
the compound containing tantalum is at least one of TaBN, TaB, TaBSi, TaBSiN, TaN, TaSi, TaSiN, TaGe, TaGeN, TaHf, TaHfN, TaZr, and TaZrN.

9. The reflective photomask of claim 1, wherein
the phase shift portion is surrounded by the semi-light-absorbing portion, and
the semi-light-absorbing portion is surrounded by the reflective portion.

10. The reflective photomask of claim 1, wherein
the phase shift portion and the reflective portion are surrounded by the semi-light-absorbing portion.

11. A manufacturing method of a reflective photomask comprising the steps of:
(a) sequentially forming a first multilayer film reflective to exposure light, a first interlayer film, a second multilayer film, a second interlayer film, and a third multilayer film on a glass substrate;
(b) forming a phase shift portion by etching the third multilayer film, the second interlayer film, the second multilayer film, and the first interlayer film;
(c) forming a reflective portion by etching portions of the third multilayer film and the second interlayer film which are located outside the phase shift portion; and
(d) forming a semi-light-absorbing portion by retaining portions of the third multilayer film, the second interlayer film, the second multilayer film, the first interlayer film, and the first multilayer film which are located between the phase shift portion and the reflective portion without etching the portions.

12. The method of claim 11, wherein
0.95≦4(m1+d1)cos φ/(2n−1)λ≦1.05, where n is an integer,
and
0.95≦4(m2+d2)cos φ/2nλ≦1.05, where n is an integer, where the first interlayer film has a thickness of m1, the second multilayer film has a thickness of d1, the second interlayer film has a thickness of m2, the third multilayer has a thickness of d2, an incident angle of the exposure light is φ, and the exposure light has a wavelength of λ.

13. The method of claim 11, wherein
the first interlayer film contains at least one of silicon dioxide, silicon nitride, ruthenium, and a compound containing ruthenium, and
the second interlayer film contains a compound containing tantalum.

14. The method of claim 13, wherein
the compound containing ruthenium is at least one of RuB, RuSi, RuNb, RuZr, RuMo, RuY, RuTi, and RuLa.

15. The method of claim 13, wherein
the compound containing tantalum is at least one of TaBN, TaB, TaBSi, TaBSiN, TaN, TaSi, TaSiN, TaGe, TaGeN, TaHf, TaHfN, TaZr, and TaZrN.

16. The method of claim 11, wherein
the step (b) includes the steps of
dry-etching the third multilayer film, the second interlayer film, and the second multilayer film, and
wet-etching the first interlayer film.

17. The method of claim 11, wherein
the step (c) includes the steps of
dry-etching the third multilayer film, and
wet-etching the second interlayer film.

18. A pattern formation method forming a pattern on a substrate, the method comprising
a formation step of a resist film on the substrate;
an exposure step irradiating the resist film with light reflected by the reflective photomask of claim 1; and
a development step forming the pattern by developing the resist film after the exposure step.

19. The method of claim 18, further comprising
a formation step of an underlying organic film on the substrate before the formation step of the resist film.

20. The method of claim 18, wherein
the exposure light has a wavelength of 13.6 nm.
